(19) United States
(12) Patent Application Publication
(10) Pub. No.: US 2012/0139633 A1
(43) Pub. Date: Jun. 7, 2012

(54) SEMICONDUCTOR INTEGRATED CIRCUIT AND TUNER SYSTEM INCLUDING THE SAME

(75) Inventors: Takafumi Nasu, Tokushima (JP); George Hayashi, Osaka (JP); Katsumasa Hijikata, Osaka (JP)

(73) Assignee: Panasonic Corporation, Osaka (JP)

(21) Appl. No.: 13/398,318

(22) Filed: Feb. 16, 2012

Related U.S. Application Data
(63) Continuation of application No. PCT/JP2011/000055, filed on Jan. 7, 2011.

(30) Foreign Application Priority Data
Jul. 30, 2010 (JP) 2010-172062

(51) Int. Cl. H03F 3/45; H03F 3/04; H03L 5/00; H03G 3/00

(52) U.S. Cl. 330/254; 330/284; 330/307; 327/308

(57) ABSTRACT

A presented semiconductor integrated circuit, which processes an RF signal, achieves preferable distortion characteristics even at the low supply voltage. It includes an attenuator configured to attenuate an input signal with a variable attenuation, a source follower configured to receive an output of the attenuator, and an amplifying unit configured to perform a filtering process on an output of the source follower, and then amplify the output of the source follower with a variable gain.

### CROSS-REFERENCE TO RELATED APPLICATION

This is a continuation of PCT International Application PCT/JP2011/000055 filed on Jan. 7, 2011, which claims priority to Japanese Patent Application No. 2010-172062 filed on Jul. 30, 2010. The disclosures of these applications including the specifications, the drawings, and the claims are hereby incorporated by reference in their entirety.

### BACKGROUND

The present disclosure relates to semiconductor integrated circuits, and specifically to low-distortion, low-noise RF signal processing circuit suitable for a front end of a tuner system.

For tuner systems, to extract desired information from a received wide band radio-frequency (RF) signal such as a digital terrestrial television broadcasting signal, low-noise and low-distortion characteristics are required. For example, Integrated Services Digital Broadcasting-Terrestrial (ISDB-T) in Japan consists of 50 channels ranging from channel 13 (473.143 MHz) to channel 62 (767.143 MHz), and the signal band width of each channel is 6 MHz. In general, a tuner system is required to realize high sensitivity of less than −80 dBm and good immunity to the interference signal of more than 50 dBc.

The reception characteristics of tuner systems depend on the noise characteristic and the linearity of an RF signal processing circuit on a tuner front end. In general, an RF signal received at a tuner system is processed in an attenuator according to the input signal strength, and then the attenuator output is amplified. When the input level of the RF signal is high, it is suppressed in the attenuator to keep preferable linearity of the RF signal processing circuit. In contrast, when the input level of the RF signal is low, the signal attenuation is decreased to retain a preferable noise characteristic of the RF signal processing circuit (see, for example, Japanese Patent Publication No. 2001-008179).

RF signal processing circuits used as front ends of tuner systems are generally implemented as semiconductor integrated circuits. In recent years, further reduction in size of the semiconductor integrated circuits and power consumption of the tuners has been required, and a supply voltage is decreasing in deep-submicron CMOS process. However, as the supply voltage of the RF signal processing circuit decreases, the linearity of amplifiers degrades. For example, as illustrated in the following table, when the power supply voltage is reduced from 3.3 V to 1.2 V, IIP3 of the RF signal processing circuit degrades by about 6 dB. This means that the immunity to the interference signal degrades by 12 dBc. Therefore, it is difficult to reduce the size and the supply voltage of semiconductor integrated circuits including RF signal processing circuits.

TABLE 1

| Power Supply | | | |
|---|---|---|---|
| Voltage | Gain [dB]*¹ | Noise Figure [dB]*¹ | IIP3 [dBm]*² |
| 3.3 V | 2.0 | 14.5 | 23.1 |
| 1.2 V | 1.8 | 13.9 | 16.7 |

*¹The evaluation is performed at 500 MHz.
*²The evaluation is performed by using two-tone signals of 500 MHz and 505 MHz.
IIP3 is calculated by using an output power of a 505 MHz fundamental component and that of a 510 MHz third-order distortion component.

### SUMMARY

The present invention realizes preferable linearity of an RF signal processing circuit implemented as a semiconductor integrated circuit even at a low supply voltage.

A semiconductor integrated circuit includes an attenuator configured to suppress an input signal with a variable attenuation, and a source follower configured to receive an output of the attenuator. The semiconductor integrated circuit may further include a filter unit configured to perform a filtering process on an output of the source follower, or an amplifying unit configured to perform a filtering process on the output of the source follower and then amplify the output of the source follower with a variable gain. Specifically, the amplifying unit includes a filter unit configured to perform a filtering process on the output of the source follower, and a variable gain amplifier configured to amplify an output of the filter unit with a variable gain. With this architecture, an attenuated signal enters a following block via the source follower, so that the distortion in the following block can be inhibited even at a low supply voltage. Moreover, when the output of the source follower is subjected to the filtering process, and then enters the following block, the tuner's immunity to the interference signal can be further improved.

Preferably, the semiconductor integrated circuit includes a low-noise amplifier which has a common input terminal with the attenuator, and a multiplexer configured to selectively output any one of outputs of the source follower and the low-noise amplifier. An output of the multiplexer is provided to the filter unit or the amplifying unit. This can lead the noise characteristic of a tuner system to be lower.

### BRIEF DESCRIPTION OF THE DRAWINGS

FIG. 1 is a block diagram of an RF signal processing circuit according to a first embodiment of the present invention.

FIG. 2 is a block diagram of an RF signal processing circuit according to a variation of the present invention.

FIG. 3 is a schematic diagram of an attenuator.

FIG. 4 is a schematic diagram of the attenuator of another variation.

FIG. 5 is a schematic diagram of a source follower.

FIG. 6 is a schematic diagram of an amplifying unit.

FIG. 7 is a schematic diagram of a tracking filter.

FIG. 8 is a schematic diagram of a filter unit.

FIG. 9 is a block diagram of a differential RF signal processing circuit according to a variation of the present invention.

FIG. 10 is a schematic diagram of a differential attenuator.

FIG. 11 is a schematic diagram of an RF signal processing circuit according to a second embodiment of the present invention.

FIG. 12 is a schematic diagram of an RF signal processing circuit according to a variation of the present invention.

FIG. 13 is a block diagram of a tuner system according to a third embodiment of the present invention.

### DETAILED DESCRIPTION

### First Embodiment

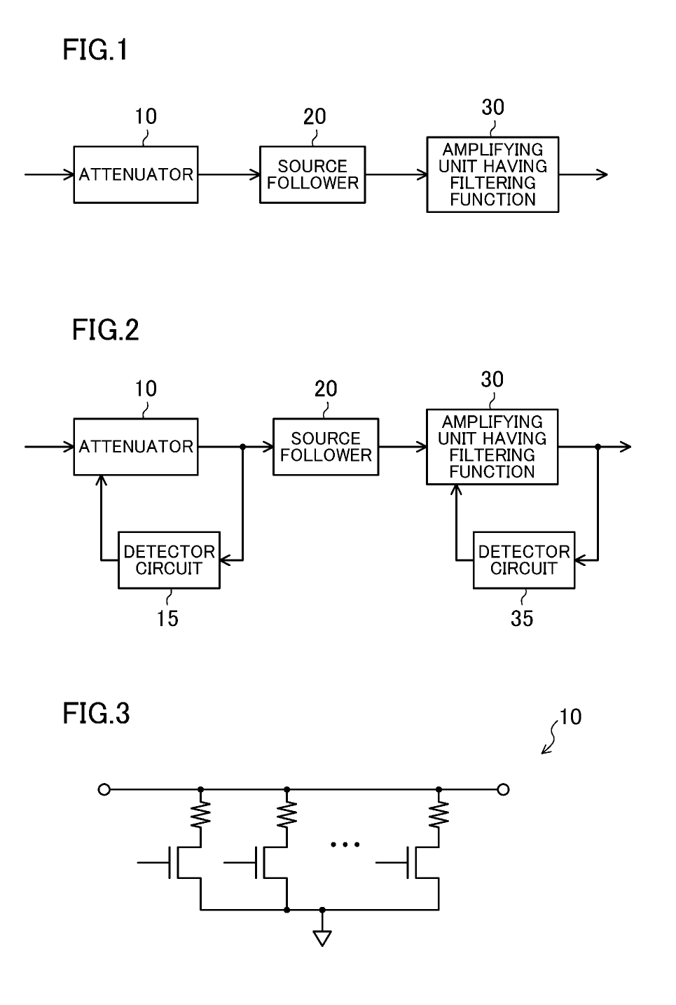

FIG. 1 illustrates a block diagram of an RF signal processing circuit according to a first embodiment. The RF signal processing circuit of the present embodiment includes an attenuator 10, a source follower 20, and an amplifying unit 30. These can be implemented by using a CMOS process. An input signal to the attenuator 10 is processed with a variable attenuation, and then the attenuated signal via the source follower 20 is amplified in the amplifying unit 30. The amplifying unit 30 has a filtering function, and performs a filtering process on an output of the source follower 20. After the filtering process, the amplifying unit 30 amplifies the output of the source follower 20 with a variable gain.

As illustrated in FIG. 2, the variable attenuation of the attenuator 10 and the variable gain of the amplifying unit 30 may be adaptively controlled by detector circuits 15, 35, respectively. The detector circuit 15 detects the output level of the attenuator 10 with a threshold value of, for example, −20 dBm. The detector circuit 15 may detect the output level of the source follower 20. The detector circuit 35 detects the output level of the amplifying unit 30 with a threshold value of, for example, −10 dBm. The detection of the output level may be any detection as long as signal strength such as a peak level or an average level can be detected.

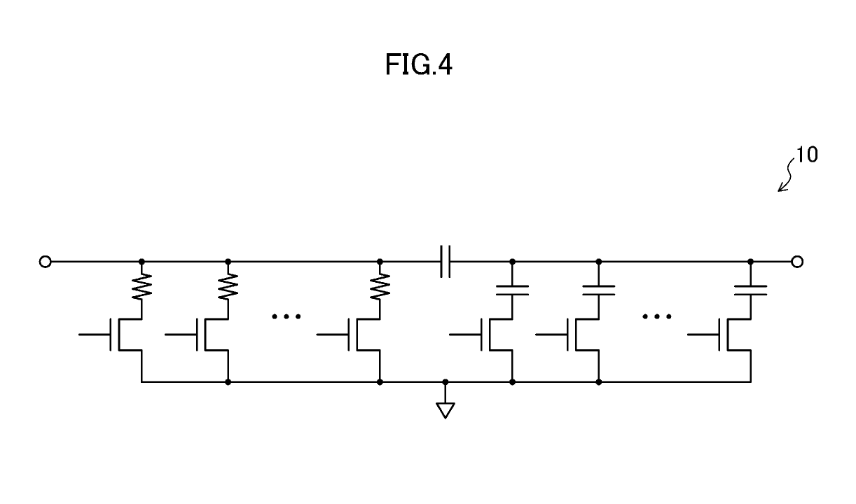

FIG. 3 illustrates an example of the attenuator 10. The attenuator 10 may include a plurality of switch resistor circuits connected to each other in parallel, each switch resistor circuit including a resistive element and a switch transistor which are connected to each other in series. The impedance of the attenuator 10 can be digitally controlled based on a switching state of each switch transistor. A signal line of an RF signal has a characteristic impedance of 50Ω or 75Ω. The attenuation depends on the proportion of the characteristic impedance to the impedance of the attenuator 10, so that the attenuation can be digitally controlled. Moreover, as illustrated in FIG. 4, if a capacitive voltage divider circuit including a capacitive element and a switch transistor is added, the variable range of the attenuation of the attenuator 10 can be extended. In addition, an LC resonant circuit is inserted into the input of the attenuator 10 to provide impedance matching with the signal line, thereby providing a gain, so that noise characteristics can be improved.

FIG. 5 illustrates an example of the source follower 20. To allow the attenuator 10 to control the attenuation by a resistive voltage divider, the input impedance of the source follower 20 is sufficiently higher than the characteristic impedance of the signal line (e.g., input capacitance is about 100 fF). The source follower 20 does not amplify a voltage input signal by non-linear transconductance, so that it has better linearity than the amplifier. A high-level RF signal is significantly suppressed in the attenuator 10, and then the attenuated signal enters the source follower 20. Thus, distortion caused in the source follower 20 can be sufficiently reduced. For example, under the condition of Table 1, a gain of 1.5 dB and an IIP3 of 23.6 dBm can be achieved even at a 1.2 V supply voltage. IIP3 is improved by about 7 dB compared to the conventional one. This means that the immunity to the interference is improved by 14 dBc, and it corresponds to the linearity of the conventional architecture operating at a 3.3 V supply voltage.

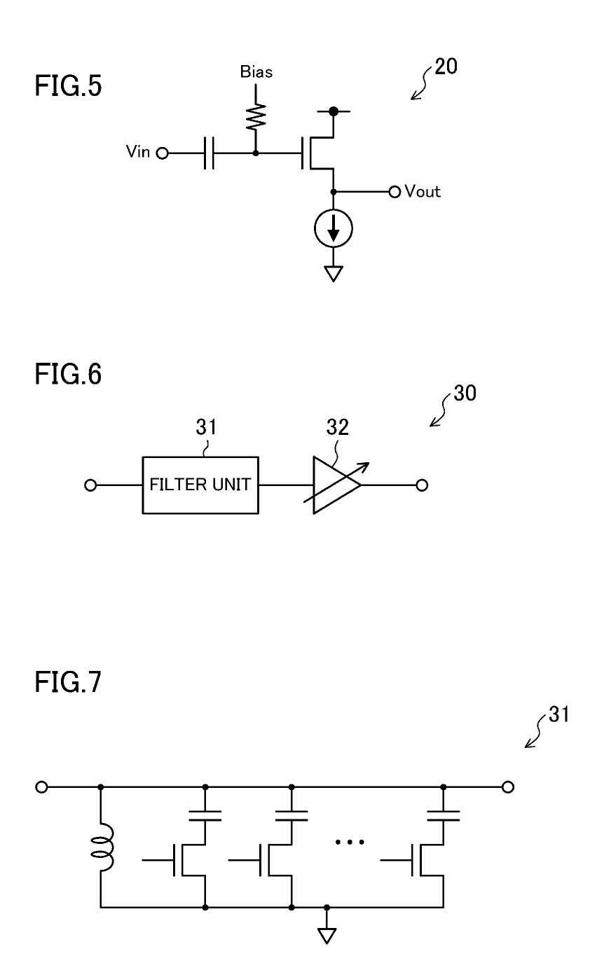

FIG. 6 illustrates an example of the amplifying unit 30. The amplifying unit 30 may include a filter unit 31 performing a filtering process on the output of the source follower 20. A variable gain amplifier 32 amplifies an output of the filter unit 31 with a variable gain.

As illustrated in FIG. 7, the filter unit 31 may be configured as a tracking filter including a plurality of switch capacitor circuits connected to each other in parallel, and an inductor connected in parallel to the switch capacitor circuits. Each switch capacitor circuit includes a capacitive element and a switch transistor connected to each other in series. The center frequency of the tracking filter can be controlled in response to the frequency of a desired channel. For example, when the inductor is 20 nH, and each switch capacitor circuit is variable from 200 fF to 10 pF, the tuning frequency range of the tracking filter is from about 300 MHz to 2.5 GHz. Moreover, when the Q value of the tracking filter is about 20, an interference signal which is 100 MHz away from a desired signal can be suppressed by 18 dB. Note that the source follower 20 has output power sufficient to drive the tracking filter. Also, as long as the center frequency of the band-pass filter can be controlled in response to the frequency of the desired channel, the architecture of the tracking filter is not limited to that of FIG. 7.

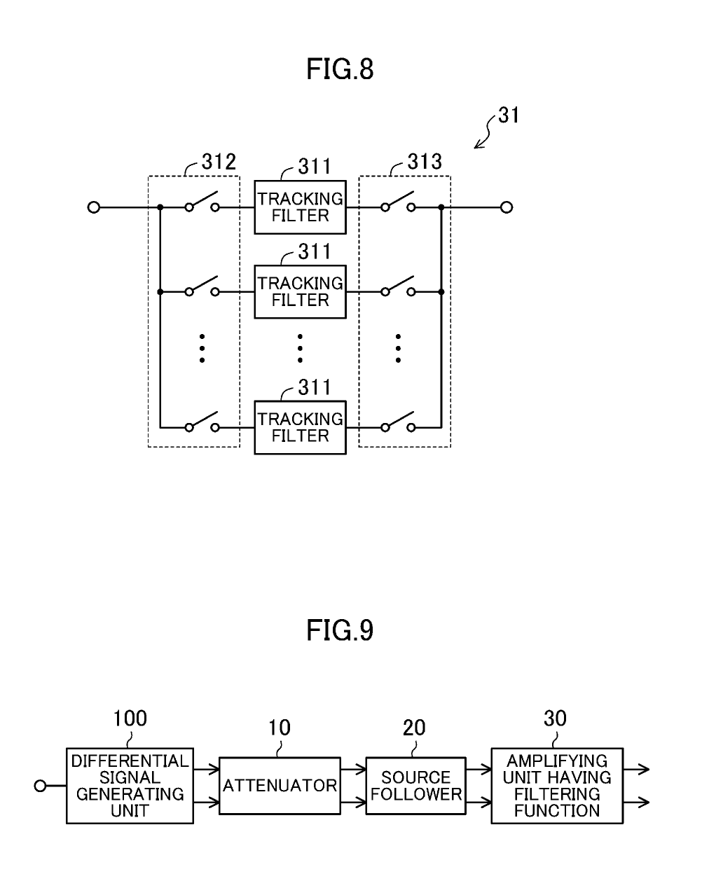

FIG. 8 illustrates another example of the filter unit 31. The filter unit 31 may include a plurality of tracking filters 311 having different tuning frequency ranges, a demultiplexer 312 configured to selectively input an output of the source follower 20 into any one of the tracking filters 311, and a multiplexer 313 configured to selectively output any one of outputs of the tracking filters 311. By controlling the selection operation of the demultiplexer 312 and the multiplexer 313 based on a received frequency, the tuning frequency range can be extended.

As described above, in the present embodiment, an input RF signal is attenuated in the attenuator 10. Then, the attenuated RF signal via the source follower 20 is amplified in the amplifying unit 30. Thus, distortion components at the output of the amplifying unit 30 can be reduced even at a low supply voltage. Moreover, before the amplification, the filtering process is performed, so that the immunity to the interference signal can be improved. As the CMOS microfabrication progresses, the transistor capability is improved, and degradation in noise figure due to the loss in the source follower 20 is reduced. That is, the RF signal processing circuit of the present embodiment is very effective in reducing the size and the voltage of semiconductor integrated circuits.

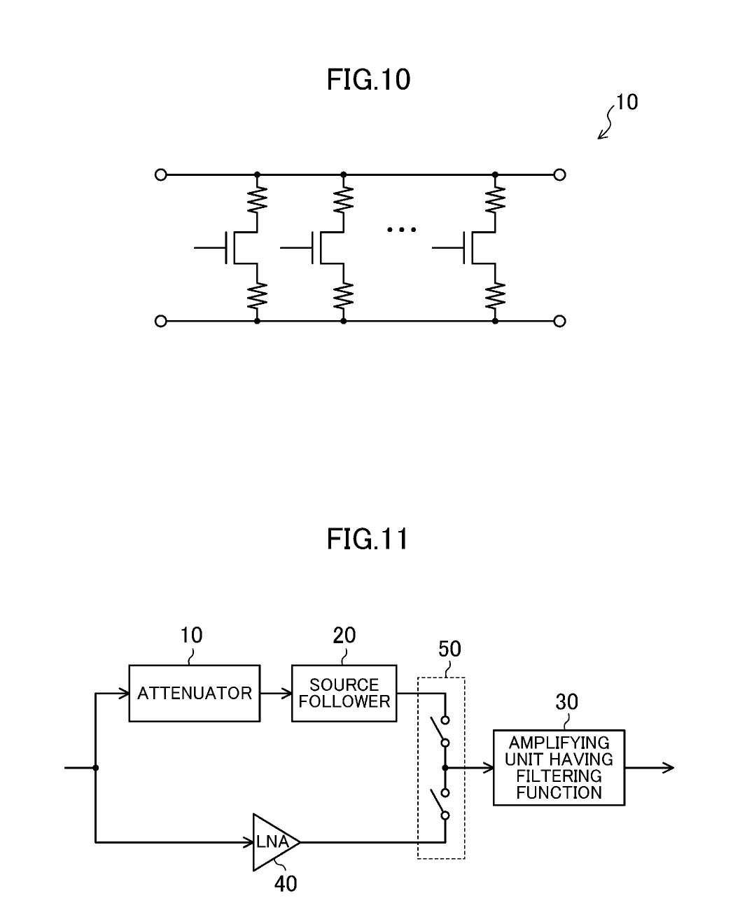

Note that as illustrated in FIG. 9, a differential signal generating unit 100 may be provided before the attenuator 10 to convert a single-phase RF signal to a differential signal. The differential signal generating unit 100 may be part of the semiconductor integrated circuit, or an external component. When the differential signal generating unit 100 is provided, the attenuator 10, the source follower 20, and the amplifying unit 30 each process the differential signal. For example, as illustrated in FIG. 10, the attenuator 10 may include a plurality of switch resistor circuits connected to each other in parallel, each switch resistor circuit including two resistive elements and a switch transistor sandwiched between the resistive elements. The switch resistor circuit may include two switch transistors and a resistive element sandwiched between the switch transistors. The differential signal can be generated by a balun. The amplitude error of the differential signal caused by the balun is about 5%. Thus, after the processes are performed on the differential signal, the differential signal is reconverted into the single-phase signal, so that a second distortion component is reduced by about 26 dB. Moreover, using the balun can provide impedance matching with the signal line, and provide a gain to improve the noise characteristic. For example, when a balun having a turns ratio of 1:4 is used, the gain is improved by about 6 dB.

### Second Embodiment

FIG. 11 illustrates an RF signal processing circuit according to a second embodiment. The RF signal processing circuit of the present embodiment is formed by adding to the RF signal processing circuit of the first embodiment, a low-noise amplifier (LNA) 40 which has a common input terminal with the attenuator 10, and a multiplexer 50 configured to selectively output any one of outputs of the source follower 20 and the LNA 40. The differences from the first embodiment will be described below. When the input level of the RF signal is high, the multiplexer 50 selects the output of the source follower 20. In contrast, when the input level of the RF signal is low, the multiplexer 50 selects the output of the LNA 40. The threshold value is, for example, −50 dBm. In this way, based on the input level of the RF signal, signal paths are accordingly switched, so that the noise figure of the RF signal processing circuit can be reduced. For example, when the gain of the LNA 40 is 20 dB, and the noise figure of the LNA 40 is 2 dB, the noise figure of the RF signal processing circuit is reduced by about 1 dB to 2 dB.

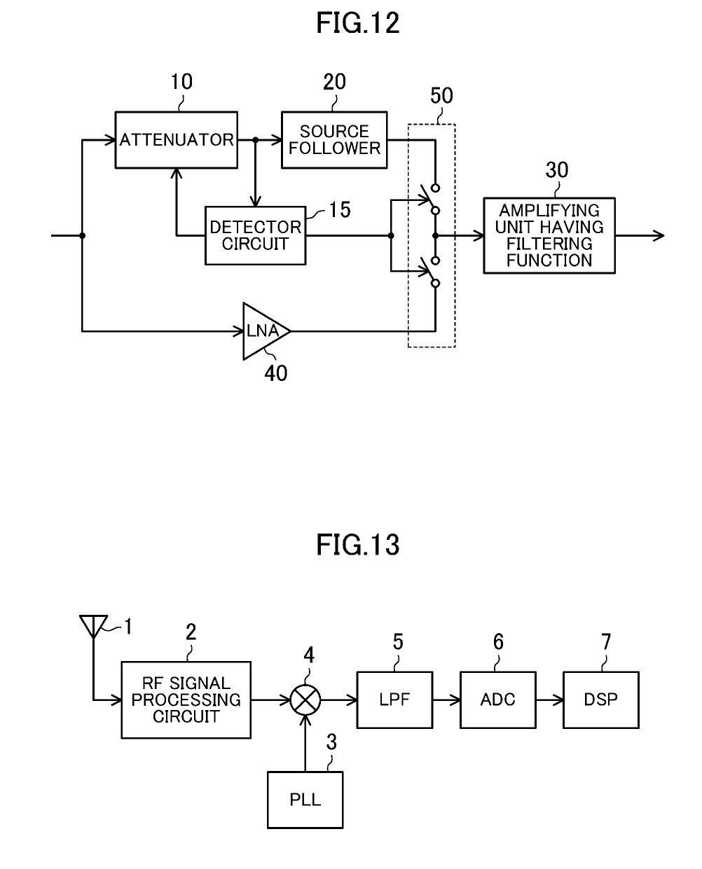

As illustrated in FIG. 12, the selection operation of the multiplexer 50 can be controlled by a detector circuit 15 configured to detect the output level of the attenuator 10. The detector circuit 15 controls the attenuation of the attenuator 10 with a threshold value of −20 dBm, and controls the selection operation of the multiplexer 50 with a threshold value of −50 dBm. That is, when the output level of the attenuator 10 is higher than −50 dBm, the detector circuit 15 indicates the control signal to select the output of the source follower 20. In contrast, when the output level of the attenuator 10 is lower than −50 dBm, the detector circuit 15 indicates the control signal to select the output of the LNA 40. As described above, detection in one detector circuit 15 with two different threshold values can be performed by switching two threshold values in a time-sharing manner. Note that a detector circuit for controlling the multiplexer 50 may be provided independently of the detector circuit 15.

Note that on an output of the LNA 40, a source follower may be provided. With this architecture, output impedances of the signal paths subjected to the selection by the multiplexer 50 can be equalized, so that the drift of a tuning frequency in a filtering process in the amplifying unit 30 due to the difference between the signal paths can be reduced. Moreover, when the gain of the amplifying unit 30 is controlled in response to the selection of the signal paths, the gain difference of the RF signal processing circuit due to the difference between the signal paths can be reduced.

In addition, the multiplexer 50 may be omitted, and any one of the source follower 20 and the LNA 40 may be selectively turned off based on the input level of the RF signal. With this architecture, power consumption can be reduced. Alternatively, when the amplifying unit 30 includes a plurality of tracking filters, a path selection circuit may be provided instead of the multiplexer 50, wherein the path selection circuit inputs any one of the output of the source follower 20 and the LNA 40 to any one of the tracking filters based on the input level and the received frequency of the RF signal.

Also, the RF signal processing circuit of the present embodiment may have a differential signal generating unit 100 providing the output to the attenuator 10 and the LNA 40 to convert a single-phase RF signal to a differential signal.

### Third Embodiment

FIG. 13 illustrates a block diagram of a tuner system according to a third embodiment. Implementation of signal processing blocks except an antenna 1 in the figure is possible by using a CMOS microfabrication process. The signal strength of an RF signal received by the antenna 1 is adjusted by an RF signal processing circuit 2. The RF signal may be provided via a cable. The RF signal processing circuit 2 is any one of the above embodiments and the above variations. The RF signal processed in the RF signal processing circuit 2 is converted by a mixer 4 to a baseband signal with a local oscillation signal generated by a PLL 3. A tuner system may be a Low-IF system, or may be a direct conversion system. After undesired high-frequency components in the baseband signal are sufficiently removed by a lowpass filter (LPF) 5, the baseband signal is converted in an A/D converter (ADC) 6 to a digital signal. Finally, in a digital signal processor (DSP) 7, a demodulation process is performed. In the DSP 7, the input level of the RF signal is detected, so that based on the results of the detection, variable characteristics of the attenuator 10 and the amplifying unit 30 in the RF signal processing circuit of FIG. 1 can be controlled.

For example, to receive digital terrestrial television broadcasting of channel 13 (473.143 MHz) in Japan, the PLL 3 outputs a local oscillation signal of 470.143 MHz, and a received RF signal is converted in the mixer 4 to a baseband signal having an intermediate frequency of 3 MHz which is the difference between the received frequency and the local oscillation frequency. In this process, a high-frequency signal of 943.286 MHz which is the sum of the received frequency and the local oscillation frequency is also generated, but such a high-frequency component is sufficiently attenuated by the LPF 5. For example, the band width of the LPF 5 is 6 MHz which is the same as the signal band of the channel. To receive another channel, the oscillation frequency of the PLL 3 is controlled based on a desired channel.

According to the tuner system of the present embodiment, a received RF signal is immediately processed in the RF signal processing circuit 2 of any one of the above embodiments and the above variations, so that low-distortion characteristics can be achieved even at the low supply voltage.

What is claimed is:

1. A semiconductor integrated circuit comprising:
an attenuator configured to attenuate an input signal with a variable attenuation;
a source follower configured to receive an output of the attenuator; and
an amplifying unit configured to perform a filtering process on an output of the source follower, and then amplify the output of the source follower with a variable gain.

2. The semiconductor integrated circuit of claim 1, wherein
the amplifying unit includes
a filter unit configured to perform a filtering process on the output of the source follower, and
a variable gain amplifier configured to amplify an output of the filter unit with a variable gain.

3. The semiconductor integrated circuit of claim 1, further comprising
a detector circuit configured to detect an output level of the amplifying unit, and to control the variable gain of the amplifying unit based on a result of the detection.

4. The semiconductor integrated circuit of claim 1, wherein
the attenuator, the source follower, and the amplifying unit each process a differential signal.

5. A semiconductor integrated circuit comprising:
an attenuator configured to attenuate an input signal with a variable attenuation; and
a source follower configured to receive an output of the attenuator.

6. The semiconductor integrated circuit of claim 5, further comprising:
a filter unit configured to perform a filtering process on an output of the source follower.

7. The semiconductor integrated circuit of claim 5, further comprising:
a low-noise amplifier which has a common input terminal with the attenuator, and
a multiplexer configured to selectively output any one of outputs of the source follower and the low-noise amplifier.

8. The semiconductor integrated circuit of claim 7, further comprising:
a detector circuit configured to detect an output level of the attenuator, and to control the variable attenuation of the attenuator and the multiplexer based on a result of the detection.

9. The semiconductor integrated circuit of claim 5, wherein
the attenuator and the source follower each process a differential signal.

10. The semiconductor integrated circuit of claim 1, further comprising:
a detector circuit configured to detect any one of output levels of the attenuator and source follower, and to control the variable attenuation of the attenuator based on a result of the detection.

11. The semiconductor integrated circuit of claim 5, further comprising:
a detector circuit configured to detect any one of output levels of the attenuator and the source follower, and to control the variable attenuation of the attenuator based on a result of the detection.

12. The semiconductor integrated circuit of claim 2, wherein
the filter unit includes a tracking filter configured to control a center frequency of a band-pass filter in response to a frequency of a desired channel.

13. The semiconductor integrated circuit of claim 6, wherein
the filter unit includes a tracking filter configured to control a center frequency of a band-pass filter in response to a frequency of a desired channel.

14. The semiconductor integrated circuit of claim 2, wherein
the filter unit includes
a plurality of tracking filters having different tuning frequency ranges,
a demultiplexer configured to selectively input the output of the source follower to any one of the plurality of tracking filters, and
a multiplexer configured to selectively output any one of outputs of the plurality of tracking filters.

15. The semiconductor integrated circuit of claim 6, wherein
the filter unit includes
a plurality of tracking filters having different tuning frequency ranges,
a demultiplexer configured to selectively input the output of the source follower to any one of the plurality of tracking filters, and
a multiplexer configured to selectively output any one of outputs of the plurality of tracking filters.

16. A tuner system comprising:
the semiconductor integrated circuit of claim 1.

17. A tuner system comprising:
the semiconductor integrated circuit of claim 5.

18. A tuner system comprising:
the semiconductor integrated circuit of claim 4; and
a differential signal generating unit configured to convert a single-phase original signal to a differential signal, and output the differential signal to the attenuator of the semiconductor integrated circuit.

19. The tuner system of claim 18, wherein
the differential signal generating unit is a balun.

20. A tuner system comprising:
the semiconductor integrated circuit of claim 9; and
a differential signal generating unit configured to convert a single-phase original signal to a differential signal, and output the differential signal to the attenuator of the semiconductor integrated circuit.

21. The tuner system of claim 20, wherein
the differential signal generating unit is a balun.
